(19) United States
(12) Patent Application Publication
(10) Pub. No.: US 2015/0042370 A1
(43) Pub. Date: Feb. 12, 2015

(54) APPARATUS FOR DETECTING A FAILED TRANSISTOR

(71) Applicant: Experium Technologies, LLC, Upper Marlboro, MD (US)

(72) Inventor: Lance Palatini, Morris Plains, NJ (US)

(73) Assignee: Experium Technologies, LLC, Upper Marlboro, MD (US)

(21) Appl. No.: 13/959,821

(22) Filed: Aug. 6, 2013

(51) Int. Cl. G01R 31/26; G01R 31/40

(52) U.S. Cl. CPC G01R 31/2621; G01R 31/40
USPC 324/750.3

(57) ABSTRACT

An electronic load system for testing power supplies, batteries, and fuel cells is characterized by its ability to automatically detect a transistor failure in the load circuit. The electronic load system includes a plurality of field effect transistor (FET) modules. Each FET module includes an FET and a differential amplifier. A processor module serves as an input to the amplifier and provides a drive signal. The FET module further includes a diode and a light emitting diode that are arranged such that the light emitting diode lights when the field effect transistor fails as an open circuit.

### BACKGROUND OF THE INVENTION

An electronic load is often used in the testing of power supplies, batteries, and fuel cells. Such an electronic load is advantageous as it can simulate numerous types of electrical characteristics on the device being tested. An appropriate electronic load may consist of multiple transistors connected in parallel and sharing current equally.

A transistorized electronic load system simulates the current drawn by a device on an electronic power source by using the current control capacity of a field effect transistor (FET). A field effect transistor is an elemental electrical device where the current through the device is controlled by the voltage applied to a specific terminal. An FET-based electronic load may generally consist of a set of FETs mounted in parallel which are controlled by adjusting the gate voltage to produce the desired current flow through the system.

However, a problem can exist when one or more transistors fail, and the current is now shared by a smaller number of transistors. The additional current through each transistor may result in additional heat leading to numerous transistor failures in a cascade effect. Accordingly, for reliability purposes, it is desirable to be able to automatically detect a transistor failure in the load circuit and to reduce or remove any applied circuit as applicable.

### BRIEF DESCRIPTION OF THE PRIOR ART

Electronic load systems utilizing FETs are known in the prior art. For example, U.S. Pat. Nos. 6,324,042 and 6,697,245, both to Andrews, disclose an electronic load for testing electrochemical energy conversion devices. These patents disclose a device in which analog and digital feedback is provided to adjust the control signal to the FETs to ensure that each remains within its individual safe operating area.

While the prior load systems provide feedback about the operation of FETs in a load system, they do not provide for automatic detection of an FET failure, in particular if the FET has failed to an open state.

The present invention was developed in order to overcome these and other drawbacks of the prior electronic load systems by providing a system that is able to automatically detect a transistor failure in the load circuit.

### SUMMARY OF THE INVENTION

Accordingly, it is a primary object of the invention to provide an electronic load system that is able to automatically detect a transistor failure in the load circuit, particularly where the transistor fails to an open state. Such an electronic load system in accordance with embodiments of the invention includes a first field effect transistor (FET) module and a second FET module coupled in parallel. The system further includes a positive terminal for connecting to the positive output of the power source to be tested. The positive terminal is connected in parallel to a source terminal of the first and second FET modules. The system also includes a negative terminal for connecting to the negative output of the power source and, in parallel, to a drain terminal of the FET modules. A processor module is connected to the FET modules and applies an external drive signal to the modules.

Each FET module includes an FET and a differential amplifier. The external drive signal from the processor module serves as an input to the amplifier. The amplifier's output is connected to the gate terminal of the FET, and in parallel to the anode of a diode. The FET module also includes a light emitting diode (LED). The FET differential amplifier, diode and light emitting diode are so arranged that the light emitting diode lights when the field effect transistor fails as an open circuit.

A further embodiment of the invention provides a load device for applying a load on a power source including an FET module. The FET module of this embodiment comprises an FET, a first differential amplifier and a second differential amplifier. The first differential amplifier has an external drive signal as an input and an output connected to a gate terminal of the FET. The second differential amplifier has an input connected to the cathode of a diode. The diode is, in turn, connected to the output of the first differential amplifier in parallel with the gate terminal of the FET. A light emitting diode is connected to the output of the second differential amplifier.

In further embodiments of the invention, the processor module includes a digital to analog converter. Embodiments may also include a communication bus that connects the processor module with a computer network interface and/or a manual control interface.

### BRIEF DESCRIPTION OF THE FIGURES

Other objects and advantages of the invention will become apparent from a study of the following specification when viewed in the light of the accompanying drawing, in which:

FIG. 1 is a circuit diagram of a field effect transistor for use in an embodiment of the present invention;

FIG. 2 is a block diagram of a transistorized electronic load system in accordance with an embodiment of the present invention; and

FIG. 3 is a circuit diagram of a field effect transistor module of an electronic load device in accordance with an embodiment of the present invention.

### DETAILED DESCRIPTION

In an embodiment of the present invention, a transistorized electronic load system simulates the current drawn by a device on an electronic power source by using the current control capacity of a field effect transistor (FET). An FET is an elemental electrical device where the current through the FET is controlled by the voltage applied to a specific terminal.

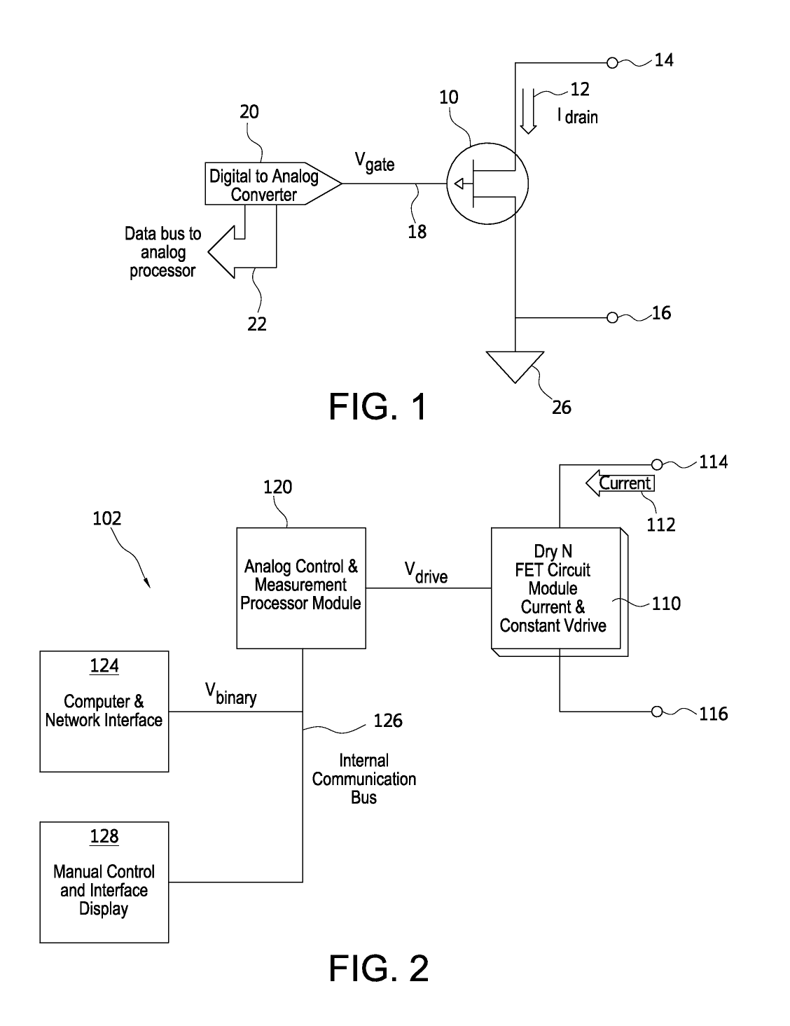

As shown in FIG. 1, a current 12 passes between a source terminal 14 and a drain terminal 16 which may generally be connected to ground 26. This current 12 may be referred to as the drain current (I_{drain}). The current 12 is proportional to a voltage applied to gate terminal 18. This voltage may be referred to as the gate voltage (V_{gate}). Accordingly, the FET can be modeled by the following simple equation:

I_{drain}=Constant*V_{gate} [Eq. 1]

In embodiments of the invention, the gate terminal 18 may be connected to a digital to analog converter 20 that provides the gate voltage (V_{gate}) to the gate terminal 18. In this manner, the current 12 across the source 14 and drain 16 terminals can be controlled. The digital to analog converter 20 may be connected to a processor by a bus 22.

As shown in FIG. 2, an electronic load system 102 may comprise multiple FET modules in a load bank 110. The FET modules of the load bank 110 may be connected in parallel to a source terminal 114 and a drain terminal 116. The load bank 24 may thus be used to achieve a current 112, which may be higher than the current that could be achieved using a single FET device.

As further illustrated in FIG. 2, a control voltage (_{Vdrive}) is applied to the load bank 110. The control voltage is created by a digital to analog voltage converter (DAC) that forms part of an analog control and measurement module, or processor module 120. The processor module 120, and its included DAC, may be connected through a communications bus 126 to a computer network interface 124, which is in turn connected to a system microprocessor. In this manner the system microprocessor sends a binary digital pattern (V_{binary}) to the processor module 120, which then generates the appropriate V_{gate} signal (FIG. 1) for each FET device 10 of the load bank 110. V_{gate} can be expressed by the following equation:

V_{gate}=Constant*V_{binary} [Eq. 2]

Combining Eq. 1 with Eq. 2, it can be seen that the current across an FET 10 is proportional to the binary digital pattern:

I_{drain}=Constant*V_{binary} [Eq. 3]

As discussed above, the user may control the applied load current 112 using a processor connected to a computer network interface 124. Alternatively, the user may control the current 112 through the use of a manual control interface 128 that is also connected to the communication bus 126, or which may be connected directly to the processor module.

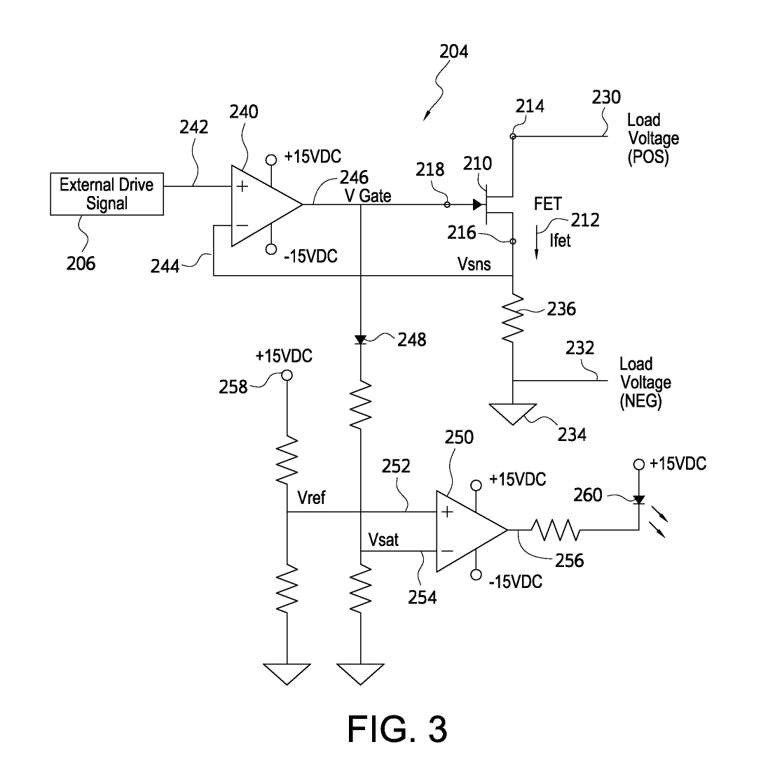

Embodiments of the present invention include a circuit capable of automatically detecting a failed FET device. FIG. 3 shows an FET module 204 for use, for example, in the load bank 110 of an electronic load system 102. Embodiments of the FET module 204 comprise a FET device 210. The FET device has a source terminal 214, a drain terminal 216 and a gate terminal 218. The source terminal 214 is connected to the positive terminal 230 of the power supply that is to be tested. Drain terminal 216 is connected to a negative terminal 232 of the power supply that is to be tested and may also be connected to ground 234. In addition, a resistor 236 may be positioned between the drain terminal 216 and the negative power supply terminal 232.

Embodiments also include a differential amplifier 240. In the embodiment illustrated in FIG. 3, a 15 volt direct current (DC) power supply is applied across the amplifier. A non-inverting input (+) 242 of the amplifier 240 is connected to an external drive signal 206, which may be the output of a digital to analog converter 20 (FIG. 1), for example. The inverting input (−) 244 of the amplifier 240 is connected to the drain terminal 216 of the FET device 210. The output 246 of the amplifier is connected to the gate terminal 218 of the FET device.

Embodiments of the invention may also include a diode 248. The anode of the diode is connected to the output of the first amplifier 240 in parallel with the gate terminal 218 of the FET device 210. The cathode of the diode 248 is connected to the inverting input (−) 254 of a second amplifier 250, which is also connected to ground. A 15 volt DC power supply is also applied across the second amplifier. In the illustrated embodiment, the non-inverting input (+) 252 of the second amplifier is connected to a +15 VDC reference voltage 258. The output 256 of the second amplifier 250 is connected to the cathode of a light emitting diode (LED) 260. A +15 VDC voltage is applied to the cathode of the LED. Further resistors and other components may be employed as shown in FIG. 3 or as would be apparent to one of ordinary skill in the art.

An embodiment of the circuit illustrated in FIG. 3 can detect a failure of the FET device 210 to an open state in the following manner: Should the FET 210 in the FET module 204 fail to an open state, zero current 212 will flow through the FET 210. Since current 212 is zero amps, the voltage (Vₛₙₛ) at the drain terminal 216 of the FET will be zero volts. If the external drive signal 206 is at any positive voltage, the voltage (V_{gate}) at the gate terminal 218 of the FET will rise to approximately +15 VDC. This causes diode 248 to conduct and consequently causes the voltage (Vₛₐₜ) at the inverting input 254 of the second amplifier 250 to be greater than the reference voltage (_{Vref}). This forces the voltage at the output 256 of amplifier 250 to −15 VDC, which causes LED 260 to conduct and light, indicating that the FET 210 has failed.

In an alternative embodiment, the inverting input 254 of amplifier 250 is connected to the parallel combination of several different diodes 248, each of which is connected to the gate voltage 218 of an individual transistor 210. In addition the LED indicator 260 may be optically coupled to a logic input on the electronic load system's processor interface.

While the preferred forms and embodiments of the invention have been illustrated and described, it will be apparent to those of ordinary skill in the art that various changes and modifications may be made without deviating from the inventive concepts set forth above.

What is claimed is:

1. A load device for applying a load on a power source, comprising
(a) at least one field effect transistor module having a source terminal connected with a positive terminal of the power source and a drain terminal connected with a negative terminal of the power source
(b) a processor module connected with said field effect transistor module to supply a drive signal;
(c) said first field effect transistor module including
(1) a field effect transistor;
(2) a first differential amplifier having the drive signal as an input and having an output connected to a gate terminal of the field effect transistor; and
(3) a light emitting diode connected with said output of said differential amplifier and being operated when said field effect transistor fails as an open circuit.

2. The load device of claim 1, wherein said first field effect transistor module further comprises a diode having an anode connected with the output of said first differential amplifier in parallel with said gate terminal of said field effect transistor.

3. The load device of claim 2, wherein said first field effect transistor module further comprises a second differential amplifier having an input connected to a cathode of said diode.

4. The load device of claim 3, wherein an output of said second differential amplifier is connected to a cathode of said light emitting diode.

5. The load device of claim 4, wherein an anode of said light emitting diode is connected to a reference voltage.

6. The load device of claim 3, wherein said first differential amplifier comprises a second input that is connected with a drain terminal of said field effect transistor.

7. The load device of claim 3, wherein said second differential amplifier includes a second input that is connected to a reference voltage.

8. The load device of claim 1, wherein said processor module comprises a digital to analog converter.

9. The load device of claim 8, and further comprising a communication bus.

10. The load device of claim 9, and further comprising a computer network interface connected to said processor module via said communication bus.

11. The load device of claim 10, and further comprising a microprocessor connected with said computer network interface.

12. The load device of claim 9, and further comprising a manual control interface connected to said processor module via said communication bus.

13. A load device for applying a load on a power source including a field effect transistor module, the field effect transistor module comprising:
(a) a field effect transistor;
(b) a first differential amplifier having an external drive signal as an input and having an output connected to a gate terminal of said field effect transistor;
(c) a diode having an anode connected with said output of said first differential amplifier in parallel with said gate terminal of said field effect transistor;
(d) a second differential amplifier having an input connected with a cathode of said diode; and
(e) a light emitting diode having a cathode connected with said output of said second differential amplifier.

14. The load device of claim 13, wherein said second differential amplifier has an input connected with a cathode of said diode.

15. The load device of claim 13, wherein an anode of said light emitting diode is connected to a reference voltage.

16. The load device of claim 13, wherein said first differential amplifier comprises a second input -connected with a drain terminal of said field effect transistor.

17. The load device of claim 13, wherein said second differential amplifier comprises a second input that is connected with a reference voltage.
